(19) United States
(12) Patent Application Publication
(10) Pub. No.: US 2026/0082643 A1
(43) Pub. Date: Mar. 19, 2026

(54) NANOSHEET FIELD-EFFECT TRANSISTORS DEPOPULATED OF NANOSHEET CHANNEL LAYERS

(71) Applicant: GlobalFoundries U.S. Inc., Malta, NY (US)

(72) Inventors: Hong Yu, Clifton Park, NY (US); Navneet Jain, Milpitas, CA (US); David Pritchard, Glenville, NY (US); Romain Feuillette, Williston, VT (US); Heather Lazar, Saratoga Springs, NY (US); Zhenyu Hu, Clifton Park, NY (US)

(21) Appl. No.: 18/885,906

(22) Filed: Sep. 16, 2024

(51) Int. Cl. H01L 29/06; H01L 27/088; H01L 29/417; H01L 29/423; H01L 29/66; H01L 29/775; H01L 29/786

(52) U.S. Cl. CPC H10D 62/116; H10D 64/258; H10D 64/518; H10D 84/83; H10D 30/014; H10D 30/43; H10D 30/6735; H10D 30/6757; H10D 62/121

(57) ABSTRACT

Structures for a nanosheet field-effect transistor and methods of forming a structure for a nanosheet field-effect transistor. The structure comprises a field-effect transistor including a first source/drain region, a second source/drain region, a nanosheet channel layer, a gate conductor layer, a first inner spacer, and a second inner spacer. The nanosheet channel layer extends laterally from the first source/drain region to the second source/drain region. The gate conductor layer includes a section positioned in a space above the nanosheet channel layer. The first inner spacer adjoins the second inner spacer, and the first and second inner spacers are positioned laterally between the section of the gate conductor layer and the first source/drain region.

### BACKGROUND

The present invention relates to semiconductor device fabrication and integrated circuits and, more specifically, to structures for a nanosheet field-effect transistor and methods of forming a structure for a nanosheet field-effect transistor.

Device structures for a field-effect transistor generally include a source region, a drain region, a channel region arranged between the source region and the drain region, and a gate electrode configured to switch carrier flow in the channel region. The channel region of a planar field-effect transistor is arranged beneath the top surface of a substrate on which the gate electrode is disposed. When a control voltage exceeding a designated threshold voltage is applied to the gate electrode, the flow of carriers in the channel region produces a device output current at, for example, the drain region.

Nanosheet field-effect transistors represent a type of non-planar field-effect transistor that may permit additional increases in packing density in an integrated circuit. The channel region of a nanosheet field-effect transistor includes multiple nanosheet channel layers that are arranged in a layer stack. The nanosheet channel layers may be initially arranged in the layer stack with sacrificial layers containing a material, such as silicon-germanium, that can be etched selectively to a material, such as silicon, constituting the nanosheet channel layers and removed. The removal of the sacrificial layers releases the nanosheet channel layers and provides open spaces for the formation of a gate electrode. Sections of the gate electrode may surround all sides of the individual nanosheet channel layers in a gate-all-around arrangement.

Improved structures for a nanosheet field-effect transistor and methods of forming a structure for a nanosheet field-effect transistor are needed.

### SUMMARY

In an embodiment, a structure comprises a field-effect transistor including a first source/drain region, a second source/drain region, a nanosheet channel layer, a gate conductor layer, a first inner spacer, and a second inner spacer. The nanosheet channel layer extends laterally from the first source/drain region to the second source/drain region. The gate conductor layer includes a section positioned in a space above the nanosheet channel layer. The first inner spacer adjoins the second inner spacer, and the first and second inner spacers are positioned laterally between the section of the gate conductor layer and the first source/drain region.

In an embodiment, a structure comprises a first field-effect transistor including a first source/drain region, a second source/drain region, a first nanosheet channel layer, a first gate conductor layer, and a first inner spacer. The first nanosheet channel layer extends laterally from the first source/drain region to the second source/drain region, the first gate conductor layer includes a section positioned in a space above the first nanosheet channel layer, the first inner spacer is positioned laterally between the first section of the gate conductor layer and the first source/drain region, the first inner spacer has a first height, and the section of the gate conductor layer has a second height. The structure further comprises a second field-effect transistor including a third source/drain region, a fourth source/drain region, a second nanosheet channel layer, a second gate conductor layer, and a second inner spacer. The second nanosheet channel layer extends laterally from the third source/drain region to the fourth source/drain region, the second gate conductor layer includes a second section positioned in a space above the second nanosheet channel layer, the second inner spacer is positioned laterally between the second section of the second gate conductor layer and the third source/drain region, the second inner spacer has a third height greater than the first height, and the section of the second gate conductor layer has a fourth height greater than the second height.

In an embodiment, a method comprises forming a layer stack including a first plurality of nanosheet channel layers, removing at least one of the first plurality of nanosheet channel layers from the layer stack to form a second layer stack including a second plurality of nanosheet channel layers, and forming a first source/drain region, a second source/drain region, and a gate conductor layer of a field-effect transistor including the second plurality of nanosheet channel layers. The second plurality of nanosheet channel layers extend from the first source/drain region to the second source/drain region.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIG. 1 is a cross-sectional view of a structure at an initial fabrication stage of a fabrication method in accordance with embodiments of the invention.

FIG. 2 is a top view of the structure at a fabrication stage subsequent to FIG. 1.

FIG. 3 is a cross-sectional view taken generally along line 3-3 in FIG. 2.

FIG. 4 is a top view of the structure at a fabrication stage subsequent to FIG. 2.

FIG. 5 is a cross-sectional view taken generally along line 5-5 in FIG. 4.

FIGS. 6-13 are cross-sectional views of the structure at successive fabrication stages subsequent to FIGS. 4, 5.

FIG. 14-15 are cross-sectional views of a structure at successive fabrication stages of a processing method in accordance with embodiments of the invention.

FIG. 16-20 are cross-sectional views of a structure at successive fabrication stages of a processing method in accordance with embodiments of the invention.

### DETAILED DESCRIPTION

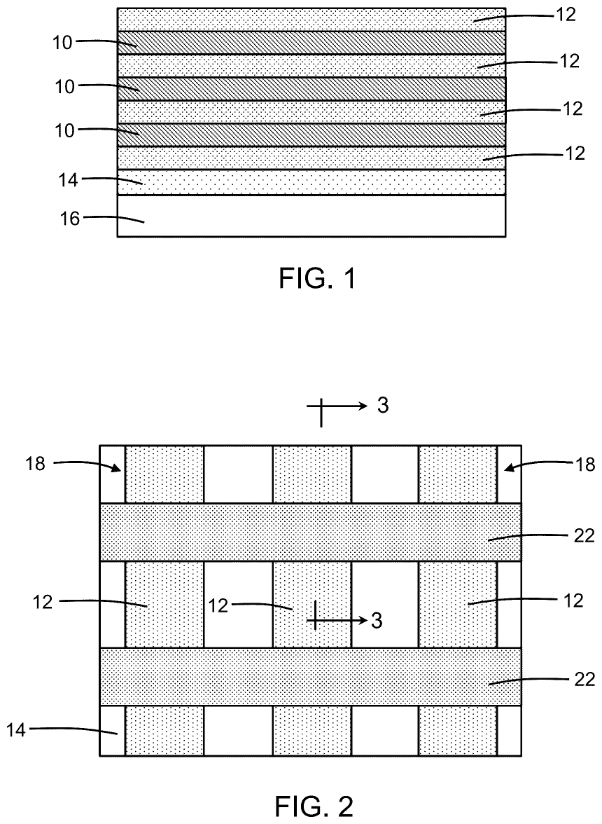

With reference to FIG. 1 and in accordance with embodiments of the invention, semiconductor layers 10 and semiconductor layers 12 are formed in an alternating sequence as a layer stack on, and over, a dielectric layer 14 and a semiconductor substrate 16. The semiconductor layers 10 may be comprised of a semiconductor material, and the semiconductor layers 12 may be comprised of a different semiconductor material. In an embodiment, the semiconductor layers 10 may be comprised of silicon-germanium with a germanium content of twenty-five percent (25%) to thirty-five percent (35%), and the semiconductor layers 12 may be comprised of silicon without a germanium content. Due to the compositional difference, the semiconductor layers 10 may be removable from the layer stack selective to the semiconductor material of the semiconductor layers 12. As used herein, the term “selective” in reference to a material removal process (e.g., etching) denotes that, with an appropriate etchant choice, the material removal rate (i.e., etch rate) for the targeted material is greater than the removal rate for at least another material exposed to the material removal process.

The semiconductor layers 10, 12 of the layer stack may be sequentially formed by an epitaxial growth process with the composition varied during growth to provide the alternating sequence. In an embodiment, the semiconductor layers 12 may contain a p-type dopant, such as boron, to provide p-type conductivity. In an alternative embodiment, the semiconductor layers 12 may contain an n-type dopant, such as arsenic or phosphorus, to provide n-type conductivity. The number of pairs of the semiconductor layers 10, 12 in the layer stack may differ from the number of pairs depicted in the representative embodiment. The semiconductor layers 12 may, after subsequent processing in the process flow, provide nanosheet channel layers in a completed device structure for a field-effect transistor. The thickness of each semiconductor layer 12 may range from about three (3) nanometers to about thirty (30) nanometers.

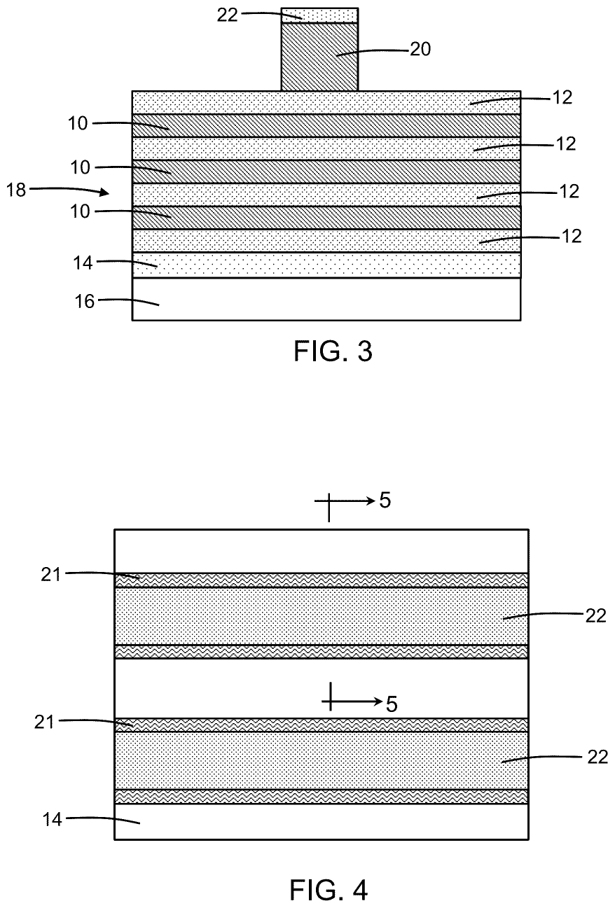

With reference to FIGS. 2, 3 in which like reference numerals refer to like features in FIG. 1 and at a subsequent fabrication stage, fins 18 are formed by patterning the semiconductor layers 10, 12 of the layer stack with lithography and etching processes. Sacrificial structures 20 are formed that extend longitudinally across the fins 18. The sacrificial structures 20 may be comprised of a polycrystalline semiconductor material, such as polycrystalline silicon (i.e., polysilicon), that is deposited by, for example, chemical vapor deposition and patterned, for example, with reactive ion etching. Each sacrificial structure 20 may be covered by a dielectric cap 22 associated with the patterning of the sacrificial structures 20. Each sacrificial structure 20 may also include a dielectric layer (not shown) comprised of, for example, silicon dioxide between the polycrystalline semiconductor material and the topmost semiconductor layer 12.

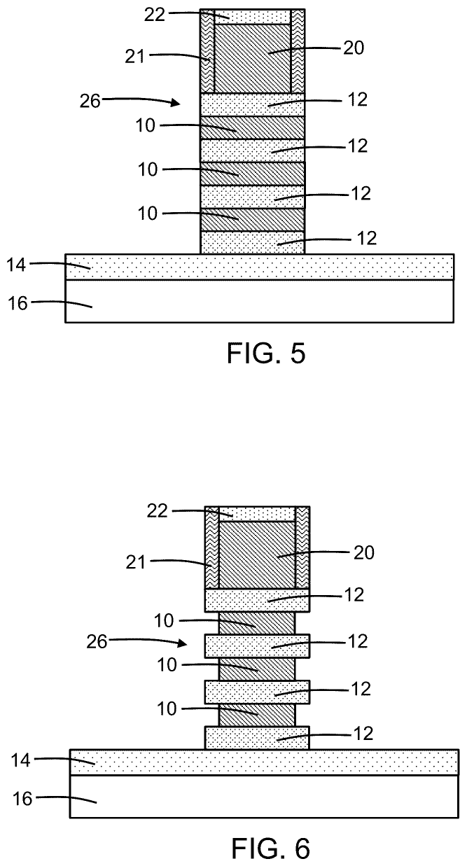

With reference to FIGS. 4, 5 in which like reference numerals refer to like features in FIGS. 2, 3 and at a subsequent fabrication stage, sidewall spacers 21 are formed on the sidewalls of each sacrificial structure 20. The sidewall spacers 21 may be formed by depositing a dielectric material, such as silicon dioxide, and performing an anisotropic etch process. After forming the sidewall spacers 21, the fins 18 may then be patterned to form bodies 26 as strips that are overlapped by the sacrificial structures 20 and sidewall spacers 21. The fins 18 may be patterned by etching with a self-aligned process that relies on the sacrificial structures 20 and sidewall spacers 21 as an etch mask. Each body 26 includes patterned semiconductor layers 10 and semiconductor layers 12 that alternate in a vertical direction to provide a stacked arrangement.

With reference to FIG. 6 in which like reference numerals refer to like features in FIGS. 4, 5 and at a subsequent fabrication stage, the semiconductor layers 10 are laterally recessed relative to the semiconductor layers 12 with a dry or wet isotropic etching process that etches the semiconductor material constituting the semiconductor layers 10 selective to the semiconductor material constituting the semiconductor layers 12. The semiconductor layers 12 are not laterally recessed due to the etch selectivity of the isotropic etching process. The lateral recessing of the semiconductor layers 10 relative to the semiconductor layers 12 produces indents in the form of recesses in the sidewalls of the bodies 26.

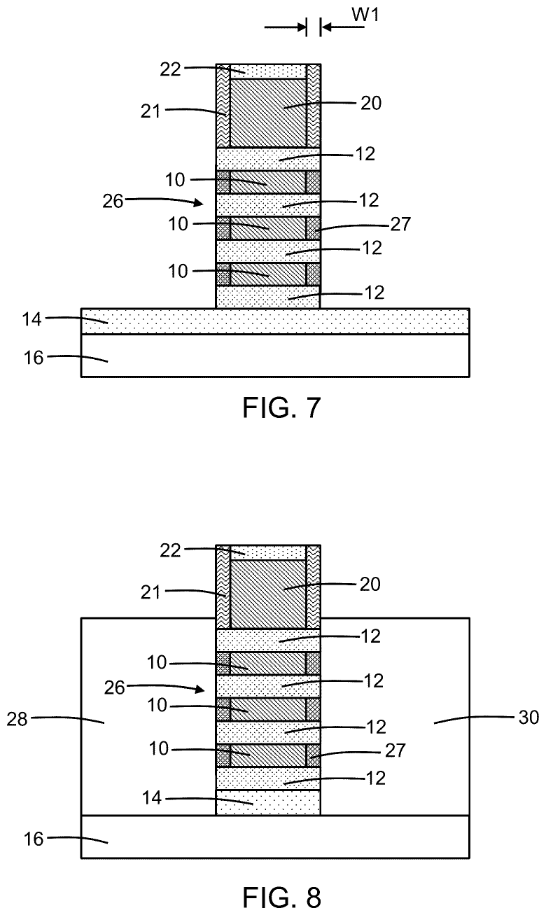

With reference to FIG. 7 in which like reference numerals refer to like features in FIG. 6 and at a subsequent fabrication stage, inner spacers 27 are formed in the indents adjacent to the opposite end portions of the semiconductor layers 10. The inner spacers 27 may be comprised of a dielectric material, such as silicon nitride, that is an electrical insulator. The inner spacers 27 may be formed by depositing a conformal layer of the dielectric material that fills the indents in the sidewalls of the bodies 26 by pinch-off, followed by performing an anisotropic etching process that removes portions of the conformal layer deposited outside of the indents. The inner spacers 27 have a width dimension W1 that may be equal to the depth of the indents in the sidewalls of the bodies 26.

With reference to FIG. 8 in which like reference numerals refer to like features in FIG. 7 and at a subsequent fabrication stage, portions of the dielectric layer 14 are removed by, for example, a pre-clean (e.g., a wet etch using dilute hydrofluoric acid or a dry etch) to expose surfaces of the semiconductor substrate 16 in the spaces between the bodies 26 and adjacent to the opposite sidewalls of each body 26. Semiconductor layers 28, 30 are formed on the exposed surfaces of the semiconductor substrate 16. The semiconductor layers 28, 30 may contain a doped semiconductor material, such as silicon doped with an n-type dopant (e.g., phosphorus) to provide n-type conductivity. The semiconductor layers 28, 30 may be formed by an epitaxial growth process in which single-crystal semiconductor material grows, optionally with in situ doping, from the exposed surfaces of the semiconductor substrate 16.

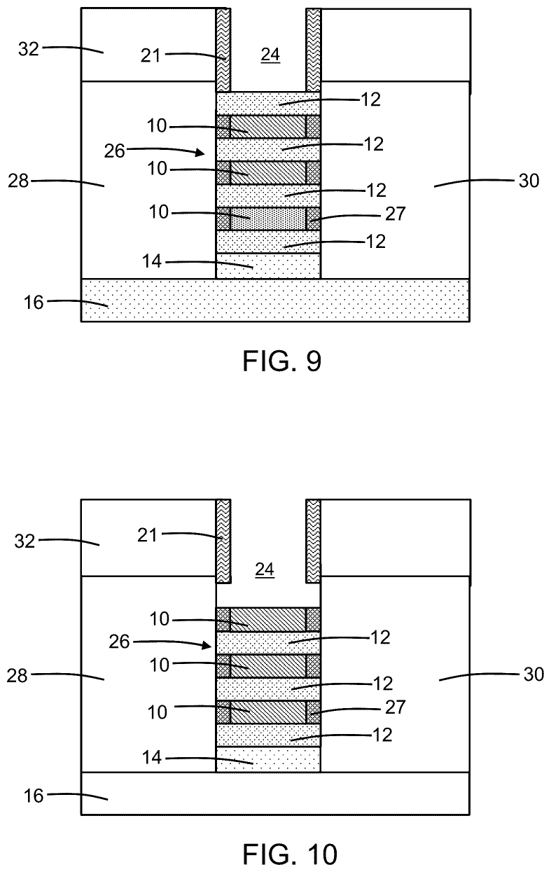

With reference to FIG. 9 in which like reference numerals refer to like features in FIG. 8 and at a subsequent fabrication stage, a dielectric layer 32 may be deposited as fill material and planarized. The dielectric layer 32 may be comprised of a dielectric material, such as silicon dioxide, deposited by chemical vapor deposition and planarized by chemical mechanical polishing. The sacrificial structures 20 and dielectric caps 22 may be removed by one or more etching processes to generate an open space 24 located above the uppermost semiconductor layer 10 in each body 26. The dielectric layer 32 protects the semiconductor layers 28, 30 during the removal of the sacrificial structures 20 and dielectric caps 22.

With reference to FIG. 10 in which like reference numerals refer to like features in FIG. 9 and at a subsequent fabrication stage, the uppermost semiconductor layer 12 is removed from the layer stack by a selective etching process to enlarge the open space 24 by adding a lower portion having the dimensions of the removed semiconductor layer 12. Notches are formed at the peripheral edges of the lower portion of the open space 24 between the sidewall spacers 21 and the uppermost set of inner spacers 27. One of the notches is laterally disposed adjacent to the semiconductor layer 28 and the other of the notches is laterally disposed adjacent to the semiconductor layer 30. The removal of the semiconductor layer 12 depopulates the number of semiconductor layers 12 relative to the original number.

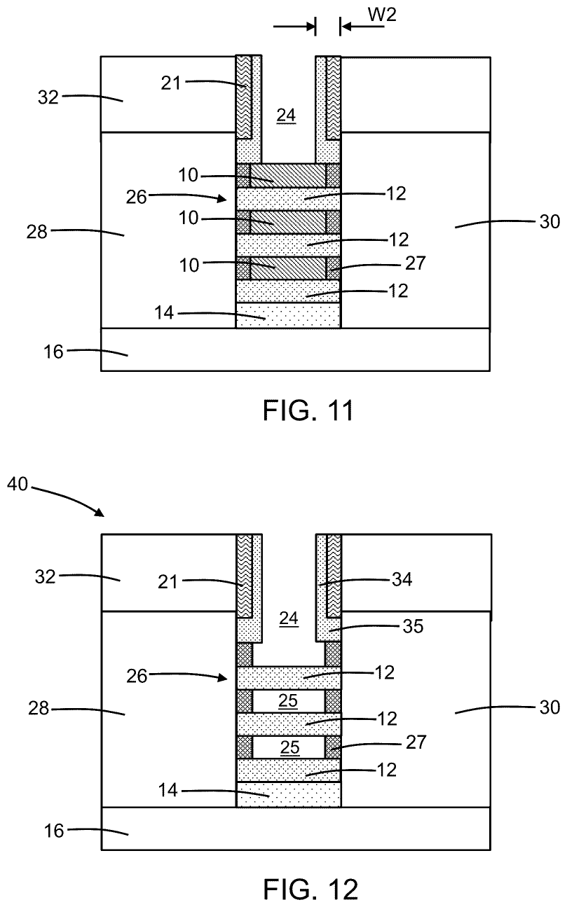

With reference to FIG. 11 in which like reference numerals refer to like features in FIG. 10 and at a subsequent fabrication stage, a dielectric layer 34 is conformally deposited that coats the sidewall spacers 21 inside the upper portion of the open space 24 and that forms inner spacers 35 that fill the notches in the lower portion of the open space 24 between the sidewall spacers 21 and the uppermost set of inner spacers 27 of each body 26. An anisotropic etching process may be performed that removes a portion of the dielectric layer 34 deposited on the uppermost semiconductor layer 10 between the inner spacers 35. The dielectric layer 34 may be comprised of a dielectric material, such as silicon dioxide or silicon nitride.

Each inner spacer 35 may be positioned with a side surface in direct contact with either semiconductor layer 28 or semiconductor layer 30. Each inner spacer 35 is positioned in a vertical direction between one of the sidewall spacers 21 and one of the inner spacers 27. Each inner spacer 35 may adjoin the underlying inner spacer 27. As used herein, the inner spacers 27 and the inner spacers 35 may adjoin because of the sharing of surfaces that are contacting or touching. In an embodiment, each inner spacer 35 may include a lower surface that directly contacts an upper surface of the underlying inner spacer 27. The lower surface of each inner spacer 35 have a width dimension W2 and surface area that is greater than the width dimension W1 and surface area of the upper surface of the underlying inner spacer 27 such that a portion of each inner spacer 35 overlaps with the underlying inner spacer 27 and a portion of each inner spacer 35 overlaps with the underlying semiconductor layer 10. The semiconductor layers 12 extend in a lateral direction, and each inner spacer 35 and the adjacent inner spacer 27 are respectively stacked in a vertical direction that is orthogonal to the lateral direction.

In an embodiment, the inner spacers 35 may be comprised of the same dielectric material as the sidewall spacers 21. In an embodiment, the inner spacers 35 may be comprised of a different dielectric material than the sidewall spacers 21. In an embodiment, the inner spacers 35 may be comprised of the same dielectric material as the inner spacers 27. In an embodiment, the inner spacers 35 may be comprised of a different dielectric material than the inner spacers 27.

With reference to FIG. 12 in which like reference numerals refer to like features in FIG. 11 and at a subsequent fabrication stage, the remaining semiconductor layers 10 are then removed from each body 26 by a selective etching process after the dielectric layer 34 and inner spacers 35 are formed. The removal of the semiconductor layers 10 generates open spaces 25 that are arranged in a vertical direction between adjacent pairs of semiconductor layers 12 and that extend in a lateral direction across each body 26 between opposite inner spacers 27. The dielectric layer 32, the inner spacers 27, and the inner spacers 35 protect the semiconductor layers 28, 30 when the etching process removing the semiconductor layers 10 is performed. The uppermost inner spacers 27 are positioned between the inner spacers 35 and the uppermost semiconductor layer 12. All semiconductor layers 12 are positioned in a vertical direction between the uppermost inner spacers 27 and the semiconductor substrate 16. The semiconductor layers 12 extend in a lateral direction, and the pairs of inner spacers 27 and inner spacers 35 are stacked in a vertical direction that is orthogonal to the lateral direction.

The semiconductor layers 12, which have a spaced arrangement in the vertical direction, of each body 26 may collectively provide nanosheet channel layers defining the channel region of a field-effect transistor 40. The semiconductor layers 28, 30 provide source/drain regions of the field-effect transistor 40, and the semiconductor layers 12 extend laterally from the semiconductor layer 28 to the semiconductor layer 30. The opposite end portions of each semiconductor layer 12 may directly contact, and may be abutted with, the semiconductor layers 28 and the semiconductor layer 30.

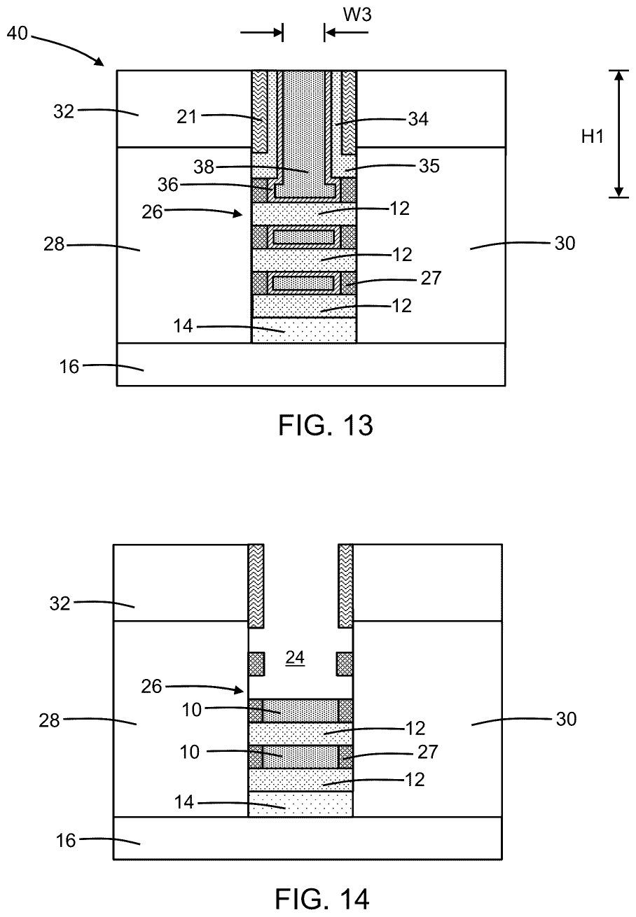

With reference to FIG. 13 in which like reference numerals refer to like features in FIG. 12 and at a subsequent fabrication stage, a gate dielectric layer 36 and a gate conductor layer 38 are sequentially formed to provide a gate structure of the field-effect transistor 40. The gate dielectric layer 36 coats the dielectric layer 32 and the outside surface of each semiconductor layer 12. The gate conductor layer 38 includes sections in the open spaces 25 of each body 26 between the semiconductor layers 12 that were formerly occupied by the removed semiconductor layers 10. More specifically, the sections of the gate conductor layer 38 may be positioned in the open spaces 25 adjacent to the central portions of the semiconductor layers 12. The inner spacers 27 are laterally positioned between the sections of the gate conductor layer 38 in the open spaces 25 and the semiconductor layers 28, 30. The gate conductor layer 38 may fully wrap around (i.e., surround) the central portion of each semiconductor layer 12. Inside each open space 25, a portion of the gate dielectric layer 36 separates the section of the gate conductor layer 38 from each adjacent semiconductor layer 12.

The gate conductor layer 38 also includes a section that forms inside the open space 24. The gate conductor layer 38 has multiple width dimensions W3 because of the presence of the inner spacers 35 and the dielectric layer 34 associated with the formation of the inner spacers 35. The inner spacers 35 are laterally positioned between the section of the gate conductor layer 38 in the open space 24 and the semiconductor layers 28, 30. The inner spacers 27 and the inner spacers 35 furnish electrical isolation between the gate conductor layer 38 and the semiconductor layers 28, 30. Pairs of the inner spacers 27 are aligned across the width of the gate conductor layer 38, and the inner spacers 35 are aligned with each other across the width of the gate conductor layer 38.

In an embodiment, the gate conductor layer 38 may be comprised of a metal, such as a work-function metal. The gate conductor layer 38 may be formed by depositing a layer of the metal and planarizing the deposited layer with, for example, chemical-mechanical polishing. In an embodiment, the gate dielectric layer 36 may be comprised of a high-k dielectric material, such as hafnium oxide, having a larger dielectric constant than silicon dioxide and a larger dielectric constant than the dielectric material constituting the inner spacers 27 and the dielectric material constituting the inner spacers 35.

The addition of the dielectric layer 34 reduces the width dimension of the upper portion of the open space 24 between the sidewall spacers 21. In an embodiment, the width dimension of the field-effect transistor 40 may be increased to compensate for the addition of the dielectric layer 34. The increase in the width dimension may provide gate resistance matching with a field-effect transistor from which the topmost semiconductor layer 12 has not been removed.

The field-effect transistor 40 includes source/drain regions provided by the semiconductor layers 28, 30, a channel region having multiple nanosheet channel layers represented by the semiconductor layers 12 that laterally connect the semiconductor layer 28 to the semiconductor layer 30, and a gate provided by the gate conductor layer 38. The number of semiconductor layers 12 can be flexibly decreased by depopulation to satisfy a set of given performance metrics for the field-effect transistor 40. The inner spacers 35 may compensate for an increase in gate-to-source capacitance and gate-to-drain capacitance produced by the depopulation that removes some of the semiconductor layers 12.

In an alternative embodiment, one of the bodies 26 may be spared the depopulation such that a field-effect transistor with a different number of semiconductor layers 12 from the field-effect transistor 40 is formed on the same semiconductor substrate 16 as the field-effect transistor 40. In an alternative embodiment, one of the bodies 26 may be depopulated of multiple semiconductor layers 12 such that a field-effect transistor with different number of semiconductor layers 12 from the field-effect transistor 40 is formed on the same semiconductor substrate 16.

With reference to FIG. 14 and in accordance with alternative embodiments, an additional semiconductor layer 10 and an additional semiconductor layer 12 may be removed such that the number of semiconductor layers 12 is further reduced. The removal of the additional pair of semiconductor layers 10, 12 further enlarges the open space 24 above the remaining semiconductor layers 10, 12.

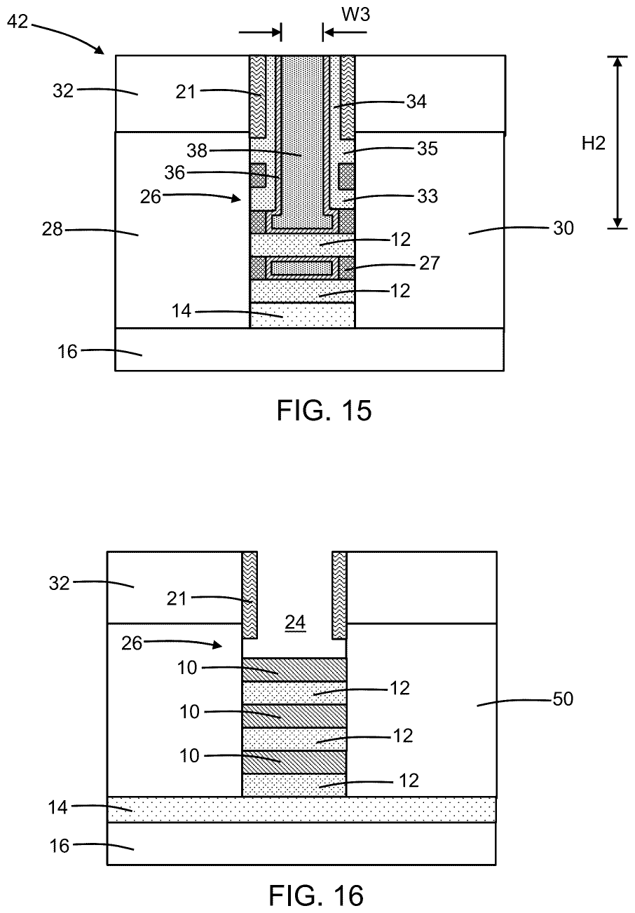

With reference to FIG. 15 in which like reference numerals refer to like features in FIG. 14 and at a subsequent fabrication stage, the dielectric layer 34 is deposited, and inner spacers 33 and inner spacers 35 are formed that fill the notches in the peripheral portions of the open space 24. After forming the spacers 33, 35, the remaining semiconductor layers 10 are removed, and the gate dielectric layer 36 and gate conductor layer 38 representing the gate structure of a field-effect transistor 42 are formed.

The lower pair of semiconductor layers 12, which are intact, represent the nanosheet channel layers of the field-effect transistor 42. Similar to the inner spacers 35, the inner spacers 33 are laterally positioned between the section of the gate conductor layer 38 in the open space 24 and the semiconductor layers 28, 30. One of the inner spacers 27 is positioned between each inner spacer 33 and one of the inner spacers 35 in a stacked arrangement. Each inner spacer 35 may have a lower surface that adjoins an upper surface of the adjacent inner spacer 27, which has a lower surface that adjoins an upper surface of the adjacent inner spacer 33. The surface area of the lower surface of the inner spacers 35 and the surface area of the upper surface of the inner spacers 33 may be larger than the surface areas of the upper and lower surfaces of the inner spacers 27. Short segments of the dielectric layer 34 extend across the intervening inner spacers 27 join the inner spacers 33 to the inner spacers 35.

The gate conductor layer 38 has multiple width dimensions W3 because of the presence of inner spacers 33, 35 and the dielectric layer 34 associated with the formation of the inner spacers 33, 35. The inner spacers 33, 35 are laterally positioned between the section of the gate conductor layer 38 in the open space 24 and the semiconductor layers 28, 30. The inner spacers 27 and the inner spacers 33, 35 furnish electrical isolation between the gate conductor layer 38 and the semiconductor layers 28, 30. Pairs of the inner spacers 27 are aligned across the width of the gate conductor layer 38, the inner spacers 33 are aligned across the width of the gate conductor layer 38, and the inner spacers 35 are aligned across the width of the gate conductor layer 38.

The section of the gate conductor layer 38 of the field-effect transistor 42 in the open space 24 has a height H2 resulting from the depopulation of the upper pair of the semiconductor layers 12. The height H2 is greater than the height H1 of the section of the gate conductor layer 38 of the field-effect transistor 40 in the smaller open space 24 resulting from depopulation of only the uppermost semiconductor layer 12.

With reference to FIG. 16 and in accordance with alternative embodiments, a sacrificial layer 50 may be formed that fills the spaces between the bodies 26. The sacrificial layer 50 may be comprised of a dielectric material, such as silicon dioxide. After forming the sacrificial layer 50, the sacrificial structures 20 and the dielectric caps 22 are removed, followed by the removal of the topmost semiconductor layer 12 to form the open space 24 and thereby depopulate the semiconductor layers 12.

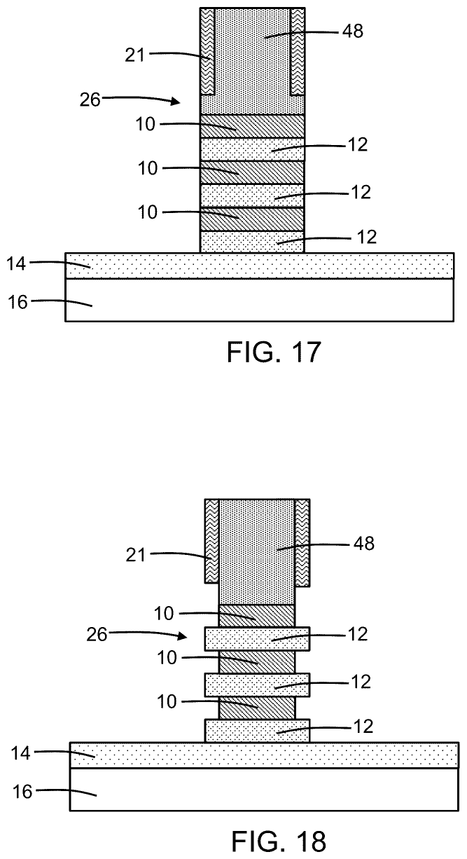

With reference to FIG. 17 in which like reference numerals refer to like features in FIG. 16 and at a subsequent fabrication stage, a sacrificial structure 48 may formed in the open space 24. In an embodiment, the sacrificial structure 48 be comprised of the same material as the semiconductor layers 10. In an embodiment, the sacrificial structure 48 be comprised of silicon-germanium. The sacrificial layer 50 may be subsequently removed.

With reference to FIG. 18 in which like reference numerals refer to like features in FIG. 17 and at a subsequent fabrication stage, the semiconductor layers 10 and a bottom portion of the sacrificial structure 48 are laterally recessed relative to the semiconductor layers 12 with a dry or wet isotropic etching process that etches the semiconductor material constituting the semiconductor layers 10 selective to the semiconductor material constituting the semiconductor layers 12. The semiconductor layers 12 are not laterally recessed due to the etch selectivity of the isotropic etching process. The lateral recessing of the semiconductor layers 10 and the bottom portion of the sacrificial structure 48 relative to the semiconductor layers 12 produces indents in the form of recesses in the sidewalls of the bodies 26. The uppermost indent in each body 26 is taller than the other underlying indents.

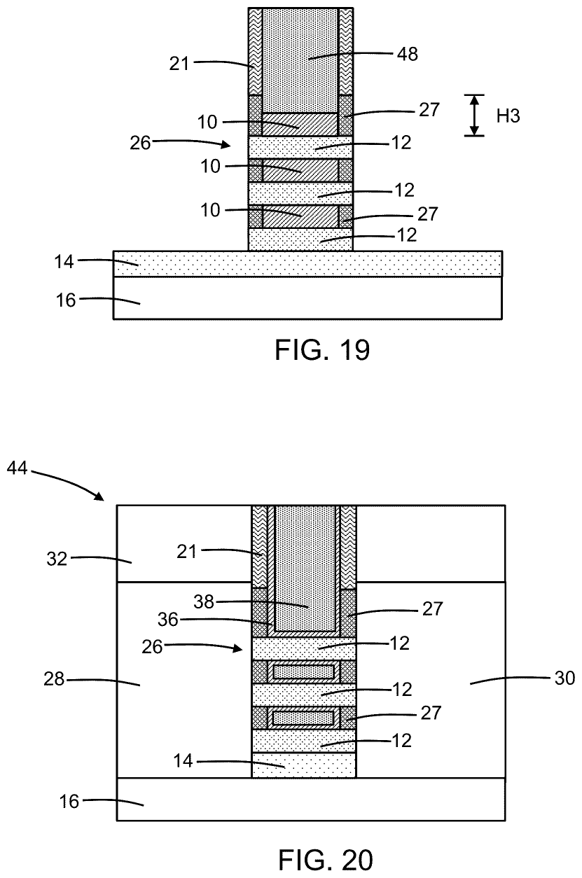

With reference to FIG. 19 in which like reference numerals refer to like features in FIG. 18 and at a subsequent fabrication stage, the inner spacers 27 are formed in the indents in each body 26. The uppermost inner spacer 27, which is formed in the uppermost indent, has a height H3 that is greater than the heights of the other underlying inner spacers 27. In an alternative embodiment, the uppermost pair of the semiconductor layers 12 and the uppermost semiconductor layer 10 may be removed such that the height of the uppermost indent is further increased and, as a result, the height H3 of the uppermost inner spacer 27 is further increased. In an alternative embodiment, the dielectric layer 34 may be formed inside the open space 24 after the sacrificial structure 48 is removed, which is deposited without forming the inner spacers 35 because of the preexisting uppermost inner spacer 27.

With reference to FIG. 20 in which like reference numerals refer to like features in FIG. 19 and at a subsequent fabrication stage, the semiconductor layers 28, 30 representing the source/drain regions of a field-effect transistor 44 are formed, followed by removal of the remaining semiconductor layers 10. The gate dielectric layer 36 and gate conductor layer 38 representing the gate structure of the field-effect transistor 44 are then formed. The lower semiconductor layers 12, which are intact, represent the nanosheet channel layers of the field-effect transistor 44.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value or precise condition as specified. In embodiments, language of approximation may indicate a range of +/−10% of the stated value(s) or the stated condition(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. Different features may “overlap” if a feature extends over, and covers a part of, another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a field-effect transistor including a first source/drain region, a second source/drain region, a first nanosheet channel layer, a gate conductor layer, a first inner spacer, and a second inner spacer, the first nanosheet channel layer extending laterally from the first source/drain region to the second source/drain region, the gate conductor layer including a first section positioned in a space above the first nanosheet channel layer, the first inner spacer adjoining the second inner spacer, and the first inner spacer and the second inner spacer positioned laterally between the first section of the gate conductor layer and the first source/drain region.

2. The structure of claim 1 wherein the first inner spacer has a surface that is in direct contact with a surface of the second inner spacer.

3. The structure of claim 2 wherein the surface of the first inner spacer has a first surface area, and the surface of second inner spacer has a second surface area that is greater than the first surface area.

4. The structure of claim 1 further comprising:
a semiconductor substrate,
wherein the first nanosheet channel layer is positioned between the first inner spacer and the semiconductor substrate, and the first inner spacer is positioned between the second inner spacer and the first nanosheet channel layer.

5. The structure of claim 1 wherein the field-effect transistor further includes a third inner spacer that adjoins the second inner spacer.

6. The structure of claim 5 wherein the first inner spacer is positioned between the second inner spacer and the third inner spacer, and the third inner spacer is positioned between the first section of the gate conductor layer and the first source/drain region.

7. The structure of claim 1 wherein the field-effect transistor includes a second nanosheet channel layer, and the gate conductor layer includes a second section in a space between the first nanosheet channel layer and the second nanosheet channel layer.

8. The structure of claim 1 wherein the field-effect transistor includes a gate dielectric layer between the first inner spacer and the gate conductor layer, and the gate dielectric layer comprises a high-k dielectric material.

9. The structure of claim 8 wherein the first inner spacer comprises silicon dioxide.

10. The structure of claim 1 wherein the first inner spacer comprises a first dielectric material, and the second inner spacer comprises a second dielectric material different from the first dielectric material.

11. The structure of claim 1 wherein the first inner spacer and the second inner spacer comprise a dielectric material.

12. The structure of claim 1 wherein the first nanosheet channel layer extends in a lateral direction, and the first inner spacer and the second inner spacer are stacked in a vertical direction that is orthogonal to the lateral direction.

13. The structure of claim 1 wherein the gate conductor layer has multiple widths.

14. The structure of claim 1 wherein the field-effect transistor including a third inner spacer and a fourth inner spacer, and the third inner spacer adjoins the fourth inner spacer.

15. The structure of claim 14 wherein the third inner spacer and the fourth inner spacer are laterally between the first section of the gate conductor layer and the second semiconductor layer.

16. The structure of claim 14 wherein the first section of the gate conductor layer is laterally between the second inner spacer and the fourth inner spacer.

17. The structure of claim 14 wherein the first inner spacer and the third inner spacer have a first width, and the second inner spacer and the fourth inner spacer have a second width greater than the first width.

18. The structure of claim 14 wherein the first inner spacer is in direct contact with the second inner spacer, and the third inner spacer is in direct contact with the fourth inner spacer.

19. A structure comprising:
a first field-effect transistor including a first source/drain region, a second source/drain region, a first nanosheet channel layer, a first gate conductor layer, and a first inner spacer, the first nanosheet channel layer extending laterally from the first source/drain region to the second source/drain region, the first gate conductor layer including a section positioned in a space above the first nanosheet channel layer, the first inner spacer positioned laterally between the first section of the gate conductor layer and the first source/drain region, the first inner spacer having a first height, and the section of the gate conductor layer having a second height; and
a second field-effect transistor including a third source/drain region, a fourth source/drain region, a second nanosheet channel layer, a second gate conductor layer, and a second inner spacer, the second nanosheet channel layer extending laterally from the third source/drain region to the fourth source/drain region, the second gate conductor layer including a second section positioned in a space above the second nanosheet channel layer, the second inner spacer positioned laterally between the second section of the second gate conductor layer and the third source/drain region, the second inner spacer having a third height greater than the first height, and the section of the second gate conductor layer having a fourth height greater than the second height.

20. A method comprising:
forming a layer stack including a first plurality of nanosheet channel layers;
removing at least one of the first plurality of nanosheet channel layers from the layer stack to form a second layer stack including a second plurality of nanosheet channel layers; and
forming a first source/drain region, a second source/drain region, and a gate conductor layer of a field-effect transistor including the second plurality of nanosheet channel layers, wherein the second plurality of nanosheet channel layers extend from the first source/drain region to the second source/drain region.
